(19) United States
(12) Patent Application Publication
(10) Pub. No.: US 2020/0243726 A1
(43) Pub. Date: Jul. 30, 2020

(54) WAVELENGTH CONVERSION MEMBER AND LIGHT EMITTING DEVICE

(71) Applicant: NIPPON ELECTRIC GLASS CO., LTD., Otsu-shi, Shiga (JP)

(72) Inventors: Hiroyuki SHIMIZU, Otsu-shi (JP); Hideki ASANO, Otsu-shi (JP)

(21) Appl. No.: 16/652,719

(22) PCT Filed: Oct. 26, 2018
(86) PCT No.: PCT/JP2018/039820

§ 371 Date: Apr. 1, 2020

(30) Foreign Application Priority Data
Nov. 21, 2017 (JP) 2017-223625

(51) Int. Cl. H01L 33/50; C09K 11/77; C09K 11/02

(52) U.S. Cl. CPC H01L 33/504; C09K 11/7706; H01L 2933/0041; H01L 2933/0091; C09K 11/02

(57) ABSTRACT

Proposed are: a wavelength conversion member having an excellent aesthetic appearance when not irradiated with excitation light and having an excellent luminescence intensity; and a light emitting device using the wavelength conversion member. A wavelength conversion member 10 includes: a first wavelength conversion layer 1 containing a phosphor; and a second wavelength conversion layer 2 formed on a surface of the first wavelength conversion layer 1 and containing phosphor nanoparticles 2a.

### TECHNICAL FIELD

The present invention relates to wavelength conversion members for converting the wavelength of light emitted from a light emitting diode (LED), a laser diode (LD) or the like to a different wavelength and light emitting devices using the same.

### BACKGROUND ART

Recently, attention has been increasingly focused on light emitting devices and the like using LEDs or LDs, as next-generation light sources to replace fluorescence lamps and incandescent lamps. As an example of such a next-generation light source, there is a disclosure of a light emitting device in which an LED capable of emitting a blue light is combined with a wavelength conversion member capable of absorbing part of the light from the LED to convert it to a yellow light. This light emitting device emits a white light which is a synthesized light of the blue light emitted from the LED and the yellow light emitted from the wavelength conversion member. Patent Literature 1 proposes, as an example of a wavelength conversion member, a wavelength conversion member in which a phosphor powder is dispersed in a glass matrix.

### CITATION LIST

### Patent Literature

[PTL 1] JP-A-2003-258308

### SUMMARY OF INVENTION

### Technical Problem

Such a wavelength conversion member having an absorption band in the visible wavelength range normally shows, when not irradiated with excitation light, a bright color originating from the phosphor powder. This can be attributed to the fact that under a white light (sunlight) the phosphor particles absorb light with an excitation wavelength to emit fluorescence originating from the phosphor and reflect light with wavelengths other than the excitation wavelength. For example, a phosphor (such as a YAG phosphor) capable of absorbing a blue excitation light to emit a yellow fluorescence not only absorbs the blue light to emit the yellow fluorescence, but also reflects a green light and a red light, and therefore shows, under a white light, a yellow color which is a mixture of the green color and the red color. For this reason, if a light emitting device with the above wavelength conversion member is incorporated into lighting equipment or other piece of equipment, it has a problem of an aesthetically unfavorable appearance due to color disharmony with surrounding members. It is conceivable to provide a coating layer on the surface of the wavelength conversion member to adjust the color of the wavelength conversion member when not irradiated with excitation light. However, in this case, there arises a problem of a significant decrease in the luminescence intensity of the wavelength conversion member obtained when irradiated with excitation light.

In view of the foregoing, the present invention has an object of proposing: a wavelength conversion member having an excellent aesthetic appearance when not irradiated with excitation light and having an excellent luminescence intensity; and a light emitting device using the wavelength conversion member.

### Solution to Problem

The inventors conducted intensive studies and, as a result, found that the above problems can be solved by a wavelength conversion member having a particular structure.

Specifically, a wavelength conversion member according to the present invention includes: a first wavelength conversion layer containing a phosphor; and a second wavelength conversion layer formed on a surface of the first wavelength conversion layer and containing phosphor nanoparticles. The term “phosphor nanoparticles” used in the present invention refers to phosphor particles having a nanosized (submicron) average particle diameter.

In the second wavelength conversion layer of the wavelength conversion member according to the present invention, light with an excitation wavelength is less likely to be absorbed into the phosphor nanoparticles under a white light and likely to be reflected and scattered on the surfaces of the phosphor nanoparticles. This can be attributed to the fact that the second wavelength conversion layer is normally composed of phosphor nanoparticles and a matrix material serving as a dispersion medium for the phosphor nanoparticles and the phosphor nanoparticles have a small particle diameter and a large specific surface area, so that a large number of interfaces between the phosphor nanoparticles and the matrix material exist in the inside of the second wavelength conversion layer, which facilitates the occurrence of light scattering. Therefore, the second wavelength conversion layer shows a white color (or a near-white color) under a white light. The phosphor nanoparticles also have a wavelength conversion function as phosphor particles to some degree and therefore contributes to the increase in luminous efficiency of the wavelength conversion member. As just described, in the wavelength conversion member according to the present invention, the second wavelength conversion layer serves as both of a coating layer for the first wavelength conversion layer when not irradiated with excitation light and a wavelength conversion layer when irradiated with excitation light. As a result, the wavelength conversion member according the present invention has a feature of an excellent aesthetic appearance when not irradiated with excitation light and an excellent luminescence intensity.

Since, as described above, the second wavelength conversion layer serves as a light scattering layer, the effect of increasing the homogeneity of light emitted from the wavelength conversion member can also be achieved.

In the wavelength conversion member according to the present invention, the phosphor contained in the first wavelength conversion layer is, for example, phosphor particles having an average particle diameter of 1 μm or more.

In the wavelength conversion member according to the present invention, the phosphor nanoparticles preferably have an average particle diameter of 10 to 400 nm.

In the wavelength conversion member according to the present invention, a concentration of the phosphor nanoparticles contained in the second wavelength conversion layer is preferably 5 to 40% by mass.

In the wavelength conversion member according to the present invention, the second wavelength conversion layer preferably has a thickness of 0.01 to 1 mm.

In the wavelength conversion member according to the present invention, the second wavelength conversion layer preferably has a thickness equal to or larger than a thickness of the first wavelength conversion layer.

In the wavelength conversion member according to the present invention, the second wavelength conversion layer preferably includes a matrix made of an inorganic material and the phosphor nanoparticles particles dispersed in the matrix. In this case, the matrix is, for example, a glass matrix.

In the wavelength conversion member according to the present invention, the first wavelength conversion layer preferably has a thickness of 0.01 to 1 mm.

In the wavelength conversion member according to the present invention, the first wavelength conversion layer preferably includes a matrix made of an inorganic material and the phosphor nanoparticles particles dispersed in the matrix. In this case, the matrix is, for example, a glass matrix.

In the wavelength conversion member according to the present invention, the first wavelength conversion layer may be made of a ceramic.

A light emitting device according to the present invention includes the above-described wavelength conversion member and a light source capable of irradiating the wavelength conversion member with excitation light.

A method for producing a wavelength conversion member according to the present invention is a method for producing the above-described wavelength conversion member and includes the steps of: preparing a green sheet for the first wavelength conversion layer and a green sheet for the second wavelength conversion layer; laying the green sheet for the first wavelength conversion layer and the green sheet for the second wavelength conversion layer one on top of the other to obtain a laminate; and firing the laminate to obtain a sintered body in which the first wavelength conversion layer and the second wavelength conversion layer are laid one on top of the other.

In the method for producing a wavelength conversion member according to the present invention, the laminate is preferably fired while being restrained between a pair of restraint members.

In the method for producing a wavelength conversion member according to the present invention, the first wavelength conversion layer and/or the second wavelength conversion layer in the sintered body are preferably polished.

In the method for producing a wavelength conversion member according to the present invention, it is preferred that the second wavelength conversion layer in the sintered body be polished to have a predetermined thickness and the first wavelength conversion layer in the sintered body be then polished to adjust a chromaticity of the wavelength conversion member.

### Advantageous Effects of Invention

The present invention enables proposition of: a wavelength conversion member having an excellent aesthetic appearance when not irradiated with excitation light and having an excellent luminescence intensity; and a light emitting device using the wavelength conversion member.

### BRIEF DESCRIPTION OF DRAWINGS

FIG. 1 is a schematic cross-sectional view of a wavelength conversion member according to an embodiment of the present invention.

FIG. 2 is a schematic cross-sectional view of a light emitting device according to an embodiment of the present invention.

### DESCRIPTION OF EMBODIMENTS

Hereinafter, a description will be given of preferred embodiments. However, the following embodiments are merely illustrative and the present invention is not limited to the following embodiments. Throughout the drawings, members having substantially the same functions may be referred to by the same reference characters.

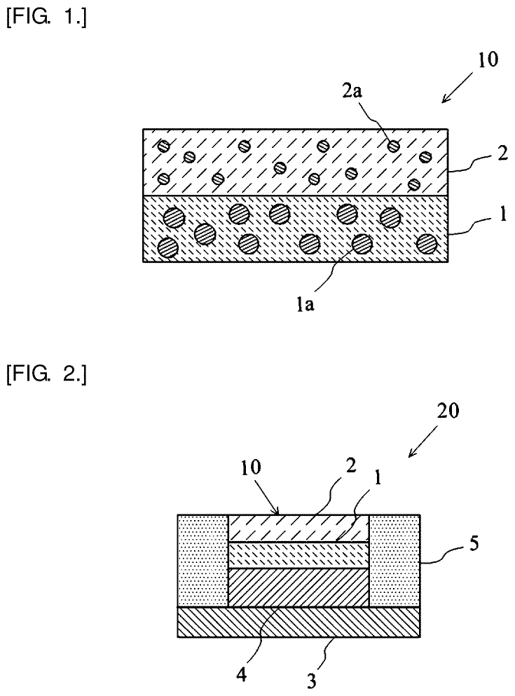

FIG. 1 is a schematic cross-sectional view showing a wavelength conversion member 10 according to an embodiment of the present invention. The wavelength conversion member 10 according to this embodiment includes: a first wavelength conversion layer 1 containing phosphor particles 1a having an average particle diameter of 1 μm or more; and a second wavelength conversion layer 2 containing phosphor nanoparticles 2a. The second wavelength conversion layer 2 is formed on a surface of the first wavelength conversion layer 1. The second wavelength conversion layer 2 may be bonded directly to the surface of the first wavelength conversion layer 1 by fusion bonding or other methods or may be bonded through an adhesive layer to the surface of the first wavelength conversion layer 1. The shape of the wavelength conversion member 10 is normally a rectangular plate-like shape.

Second wavelength conversion layers 2 may be formed on both the surfaces of the first wavelength conversion layer 1. By doing so, a stress balance can be easily kept between both the interfaces between the first wavelength conversion layer 1 and the second wavelength conversion layers 2, so that inconveniences, such as warpage, are less likely to occur.

A detailed description will be given below of each of the components.

(First Wavelength Conversion Layer 1)

The first wavelength conversion layer 1 includes: a matrix made, for example, of an inorganic material; and phosphor particles dispersed in the matrix. Specifically, the first wavelength conversion layer 1 is made of a phosphor glass containing: a glass matrix; and phosphor particles 1a dispersed in the glass matrix.

Examples of the glass matrix that can be used include a borosilicate-based glass, a phosphate-based glass, a tin-phosphate-based glass, a bismuthate-based glass, and a tellurite-based glass. Examples of the borosilicate-based glass include those containing, in terms of % by mass, 30 to 85% SiO₂, 0 to 30% Al₂O₃, 0 to 50% B₂O₃, 0 to 10% Li₂O+Na₂O+K₂O, and 0 to 50% MgO+CaO+SrO+BaO. Examples of the tin-phosphate-based glass include those containing, in terms of % by mole, 30 to 90% SnO and 1 to 70% P₂O₅. Examples of the tellurite-based glass include those containing, in terms of % by mole, 50% or more TeO₂, 0 to 45% ZnO, 0 to 50% RO (where R represents at least one selected from Ca, Sr, and Ba), and 0 to 50% La₂O₃+Gd₂O₃+Y₂O₃.

The softening point of the glass matrix is preferably 250 to 1000° C., more preferably 300 to 950° C., and still more preferably in a range of 500 to 900° C. If the softening point of the glass matrix is too low, the mechanical strength and chemical durability of the first wavelength conversion layer 1 may decrease. In addition, since the thermal resistance of the glass matrix itself is low, the glass matrix may be softened and deformed by heat generated from the phosphor particles 1a. On the other hand, if the softening point of the glass matrix is too high and in the case where the production process contains a firing step, the phosphor particles 1a may degrade in the firing step, so that the luminescence intensity of the first wavelength conversion layer 1 may decrease. From the viewpoint of increasing the chemical stability and mechanical strength of the first wavelength conversion layer 1, the softening point of the glass matrix is preferably 500° C. or more, more preferably 600° C. or more, still more preferably 700° C. or more, yet still more preferably 800° C. or more, and particularly preferably 850° C. or more. Examples of such a glass include borosilicate-based glasses. However, if the softening point of the glass matrix rises, the firing temperature also rises and, as a result, the production cost tends to rise. Furthermore, if the thermal resistance of the phosphor particles 1a is low, the phosphor particles 1a may be degraded by the firing. Therefore, in producing the first wavelength conversion layer 1 at low cost or in using phosphor particles 1a having low thermal resistance, the softening point of the glass matrix is preferably 550° C. or less, more preferably 530° or less, still more preferably 500° C. or less, yet still more preferably 480° C. or less, and particularly preferably 460° C. or less. Examples of such a glass include tin-phosphate-based glasses, bismuthate-based glasses, and tellurite-based glasses.

No particular limitation is placed on the type of the phosphor particles 1a so long as they can emit fluorescence upon incidence of excitation light. Specific examples of the phosphor particles 1a include one or more selected from the group consisting of an oxide phosphor, a nitride phosphor, an oxynitride phosphor, a chloride phosphor, an oxychloride phosphor, a sulfide phosphor, an oxysulfide phosphor, a halide phosphor, a chalcogenide phosphor, an aluminate phosphor, a halophosphoric acid chloride phosphor, and a garnet-based compound phosphor. In using a blue light as the excitation light, for example, a phosphor capable of emitting a yellow light as fluorescence can be used. An example of the phosphor capable of emitting a yellow light as fluorescence is a YAG phosphor.

The average particle diameter of the phosphor particles 1a is 1 μm or more and preferably 5 μm or more. If the average particle diameter of the phosphor particles 1a is too small, the luminescence intensity tends to decrease. On the other hand, if the average particle diameter of the phosphor particles 1a is too large, the luminescent color tends to be uneven. Therefore, the average particle diameter of the phosphor particles 1a is preferably not more than 50 μm and more preferably not more than 25 μm. Note that the average particle diameter used herein means an average particle diameter D₅₀ measured by a laser diffraction particle size distribution measurement device.

The content of the phosphor particles 1a in the first wavelength conversion layer 1 is preferably 1 to 70% by mass, more preferably 1.5 to 50% by mass, and particularly preferably 2 to 30% by mass. If the content of the phosphor particles 1a is too small, it is necessary to increase the thickness of the first wavelength conversion layer 1 in order to obtain a desired luminescent color. This results in increased internal scattering of the first wavelength conversion layer 1, which may decrease the light extraction efficiency. On the other hand, if the content of the phosphor particles 1a is too large, it is necessary to decrease the thickness of the first wavelength conversion layer 1 in order to obtain the desired luminescent color, which may decrease the mechanical strength of the first wavelength conversion layer 1.

The thickness of the first wavelength conversion layer 1 is preferably 0.01 to 1 mm, more preferably 0.03 to 0.5 mm, still more preferably 0.05 to 0.35 mm, yet still more preferably 0.075 to 0.3 mm, and particularly preferably 0.1 to 0.25 mm. If the thickness of the first wavelength conversion layer 1 is too large, scattering and absorption of light in the first wavelength conversion layer 1 may become too much, so that the efficiency of emission of fluorescence may become low. On the other hand, if the thickness of the first wavelength conversion layer 1 is too small, a sufficient luminescence intensity may be less likely to be achieved. In addition, the mechanical strength of the first wavelength conversion layer 1 may be insufficient.

The surface roughness Raᵢₙ of the first wavelength conversion layer 1 (i.e., the surface roughness of a light entrance surface of the wavelength conversion member 10) is preferably 0.01 to 0.05 μm and particularly preferably 0.015 to 0.045 μm. If Raᵢₙ is too large, incident light is scattered on the light entrance surface, so that the efficiency of light entering the inside of the wavelength conversion member 10 tends to be low. As a result, the light extraction efficiency of the wavelength conversion member 10 decreases, so that the luminescence intensity is likely to decrease. On the other hand, if Raᵢₙ is too small, the anchoring effect when the wavelength conversion member 10 is bonded to a light emitting element 4 (see FIG. 2) by an adhesive or the like is difficult to obtain, so that the bonding strength is likely to decrease. Note that if the wavelength conversion member 10 is even partially peeled from the light emitting element 4 because of a decrease in bonding strength, an air layer having a low refractive index is formed between the wavelength conversion member 10 and the light emitting element 4, so that the efficiency of incident light Lᵢₙ entering the wavelength conversion member 10 tends to significantly decrease.

An antireflection film may be provided on the surface of the first wavelength conversion layer 1. By doing so, during incidence of excitation light into the first wavelength conversion layer 1, the decrease in efficiency of excitation light entering the first wavelength conversion layer 1 due to a difference in refractive index between a resin adhesive layer (to be described hereinafter) used for the bonding to the light emitting element 4 and the first wavelength conversion layer 1 can be reduced.

The first wavelength conversion layer 1 may not be made of a phosphor glass, but instead may be formed so that the phosphor particles 1a are dispersed in a resin or may be formed so that a ceramic powder and the phosphor particles 1a are mixed and sintered. Examples of the ceramic powder include aluminum oxide, magnesium oxide, and calcium oxide. Alternatively, the first wavelength conversion layer 1 may be made of a ceramic (ceramic phosphor), such as a YAG ceramic.

(Second Wavelength Conversion Layer 2)

The second wavelength conversion layer 2 includes: a matrix made, for example, of an inorganic material; and phosphor particles dispersed in the matrix. Specifically, the second wavelength conversion layer 2 is made of a phosphor glass containing: a glass matrix; and phosphor nanoparticles 2a dispersed in the glass matrix.

Examples of the glass matrix that can be used include those given in the description of the first wavelength conversion layer 1. The glass matrixes to be used in the first wavelength conversion layer 1 and the second wavelength conversion layer 2 are preferably of the same type. In this case, there is no difference in refractive index at the interface between the first wavelength conversion layer 1 and the second wavelength conversion layer 2 (difference in refractive index between the glass matrixes), so that the reflection and scattering of light at the interface are reduced, which makes it more likely that the luminous efficiency of the wavelength conversion member 10 is increased.

Examples of the phosphor nanoparticles 2a that can be used include those given as specific examples of the phosphor particles 1a. In order to obtain a desired luminescent color, the phosphor particles 1a and the phosphor nanoparticles 2a are preferably of the same type. However, for the purpose of extracting, for example, a white light by mixing fluorescence emitted from the first wavelength conversion layer 1, fluorescence emitted from the second wavelength conversion layer 2, and excitation light, the phosphor particles 1a and the phosphor nanoparticles 2a may be of different types. Specifically, a white light can be extracted, in the presence of a blue excitation light, with the use of phosphor particles 1a capable of emitting a green light and phosphor nanoparticles 2a capable of emitting a red light (or the use of phosphor particles 1a capable of emitting a red light and phosphor nanoparticles 2a capable of emitting a green light).

The average particle diameter of the phosphor nanoparticles 2a is less than 1 μm, preferably 400 nm or less, more preferably 300 nm or less, and still more preferably 200 nm or less. If the average particle diameter of the phosphor nanoparticles 2a is too large, a desired light scattering effect tends to be difficult to be achieved. On the other hand, if the average particle diameter of the phosphor nanoparticles 2a is too small, the light scattering effect and luminescence intensity tend to decrease. Therefore, the average particle diameter of the phosphor nanoparticles 2a is preferably not less than 10 nm, more preferably not less than 50 nm, and still more preferably not less than 100 nm. The average particle diameter of the phosphor nanoparticles 2a is preferably 0.001 to 0.2 times, more preferably 0.002 to 0.1 times, and particularly preferably 0.005 to 0.05 times the average particle diameter of the phosphor particles in the first wavelength conversion layer 1. In this case, both the luminescence intensity of the first wavelength conversion layer 1 and the light scattering effect of the second wavelength conversion layer 2 are likely to be increased. As a result, a wavelength conversion member having an excellent aesthetic appearance when not irradiated with excitation light and an excellent luminescence intensity can be easily obtained.

The content of the phosphor nanoparticles 2a in the second wavelength conversion layer 2 is preferably 5 to 40% by mass, more preferably 10 to 30% by mass, and particularly preferably 15 to 20% by mass. If the content of the phosphor nanoparticles 2a is too small, the light scattering effect and luminescence intensity tend to decrease. On the other hand, if the content of the phosphor nanoparticles 2a is too large, the phosphor nanoparticles are likely to agglomerate, so that the light scattering effect tends to decrease instead or the dispersibility of the phosphor nanoparticles 2a in the second wavelength conversion layer 2 tends to decrease. In addition, the surface roughness (Raₒᵤₜ to be described hereinafter) of the second wavelength conversion layer 2 becomes too large, so that the surface grade tends to decrease.

The difference (nd) in refractive index between the glass matrix and the phosphor nanoparticles 2a is preferably 0.01 or more, more preferably 0.1 or more, and particularly preferably 0.2 or more. In this case, the light scattering at the interface between the glass matrix and the phosphor nanoparticles 2a becomes large and the degree of whiteness of the second wavelength conversion layer 2 thus becomes large, which increases the aesthetic favorability in appearance of the wavelength conversion member 10 when not irradiated with excitation light.

The thickness of the second wavelength conversion layer 2 is preferably 0.01 to 1 mm, more preferably 0.03 to 0.5 mm, still more preferably 0.05 to 0.35 mm, yet still more preferably 0.075 to 0.3 mm, and particularly preferably 0.1 to 0.25 mm. If the thickness of the second wavelength conversion layer 2 is too large, scattering and absorption of light in the second wavelength conversion layer 2 may become too much, so that the efficiency of emission of fluorescence may become low. On the other hand, if the thickness of the second wavelength conversion layer 2 is too small, the light scattering effect and luminescence intensity tend to decrease. In addition, the mechanical strength of the second wavelength conversion layer 2 may be insufficient.

When the surface roughness Raₒᵤₜ of the second wavelength conversion layer 2 (i.e., the surface roughness of the light exit surface of the wavelength conversion member 10) is increased, the return of outgoing light Lₒᵤₜ by reflection at the light exit surface is reduced, so that the light extraction efficiency is likely to increase. In addition, a white light applied from the outside to the wavelength conversion member 10 is likely to scatter at the surface of the second wavelength conversion layer 2, so that whiteness as the color of the appearance tends to increase. However, if Raₒᵤₜ is too large, the scattering of the outgoing light Lₒᵤₜ at the light exit surface becomes large, so that the light extraction efficiency is likely to decrease instead. In view of the above, the surface roughness Raₒᵤₜ of the second wavelength conversion layer 2 is preferably 0.02 to 0.25 μm, more preferably 0.04 to 0.25 μm, still more preferably 0.06 to 0.25 μm, yet still more preferably 0.07 to 0.23 μm, and particularly preferably 0.08 to 0.22 μm.

From the viewpoint of effectively increasing the light extraction efficiency of the wavelength conversion member 10, the surface roughness Raₒᵤₜ is preferably larger than the surface roughness Raᵢₙ. Specifically, Raₒᵤₜ-Raᵢₙ is preferably 0.01 μm or more, more preferably 0.02 μm or more, and particularly preferably 0.05 μm or more. However, if Raₒᵤₜ-Raᵢₙ is too large, the scattering at the light exit surface becomes large, so that the light extraction efficiency is likely to decrease instead. Therefore, Raₒᵤₜ-Raᵢₙ is preferably not more than 0.2 μm, more preferably not more than 0.18 μm, and particularly preferably not more than 0.17 μm.

The second wavelength conversion layer 2 preferably has a thickness equal to or larger than the thickness of the first wavelength conversion layer 1. In this case, the degree of whiteness of the wavelength conversion member 10 when viewed from the second wavelength conversion layer 2 side increases, so that the aesthetic favorability in appearance of the wavelength conversion member 10 when not irradiated with excitation light is increased.

The second wavelength conversion layer 2 may not be made of a phosphor glass, but instead may be formed so that the phosphor nanoparticles 2a are dispersed in a resin or may be formed so that a ceramic powder and the phosphor nanoparticles 2a are mixed and sintered. Examples of the ceramic powder include aluminum oxide, magnesium oxide, and calcium oxide.

(Method for Producing Wavelength Conversion Member 10)

A description will be given below of an example of a method for producing a wavelength conversion member 10.

A first green sheet for a first wavelength conversion layer 1 is prepared in the following manner. First, a slurry containing glass particles to be a glass matrix and phosphor particles 1 is prepared. The slurry normally contains a binder resin and a solvent. Subsequently, the prepared slurry is applied onto a supporting base material and a doctor blade spaced a predetermined distance away from the base material is moved relative to the slurry to form a first green sheet. An example of the supporting base material that can be used is a resin film made of polyethylene terephthalate or other resins.

Next, a second green sheet for a second wavelength conversion layer 2 is prepared in the following manner. A slurry containing glass particles to be a glass matrix and phosphor nanoparticles 2 is prepared and a second green sheet is obtained in the same manner as described above. The phosphor nanoparticles 2 have a small particle diameter and are, therefore, likely to agglomerate in a state of a raw material. Even if they are mixed with glass particles as they are, it is difficult to homogeneously mix both the phosphor nanoparticles 2 and the glass particles. Hence, it is preferred to first disperse into a solvent the phosphor nanoparticle 2 and a dispersant for increasing the dispersibility and then add glass powder and a binder resin into the mixture. By doing so, a slurry in which the glass particles and the phosphor nanoparticles 2 are homogeneously dispersed can be easily obtained.

The first green sheet and the second green sheet are laid one on top of the other by thermocompression bonding or other methods to obtain a laminate. The laminate is fired at a temperature of the softening point of the glass particles to the softening point of the glass particles plus about 100° C., thus obtaining a wavelength conversion member 10 formed of a sintered body in which a first wavelength conversion layer 1 and a second wavelength conversion layer 2 are laid one on top of the other. The firing is preferably performed under a reduced pressure atmosphere or particularly under a vacuum atmosphere, so that a wavelength conversion member 10 having excellent density can be easily obtained. Furthermore, the laminate is preferably fired while being restrained between a pair of restraint members. By doing so, the flatness of the wavelength conversion member 10 (particularly, the flatness of the interface between the first wavelength conversion layer 1 and the second wavelength conversion layer 2) increases, so that the wavelength conversion member 10 can be easily processed to a desired thickness in a later polishing process. Before the firing, the laminate is preferably subjected to debinder treatment at a temperature lower than the softening point of the glass particles. By doing so, the residue of organic components in the resultant wavelength conversion member 10 can be reduced, so that the luminescence intensity can be increased.

The first wavelength conversion layer 1 and/or the second wavelength conversion layer 2 in the obtained sintered body are preferably polished to have a desired thickness. Specifically, it is preferred to polish the second wavelength conversion layer 2 in the sintered body to have a predetermined thickness and then polish the first wavelength conversion layer 1 to adjust the chromaticity of the wavelength conversion member 10.

Alternatively, a wavelength conversion member 10 can be obtained by separately firing the first green sheet and the second green sheet and bonding the obtained fired bodies together by thermocompression bonding or an adhesive.

Still alternatively, a wavelength conversion member 10 can be produced in the following manner. A mixture of the glass particles and the phosphor particles 1 is fired and the obtained fired body is cut into a desired size, thus producing a first wavelength conversion layer 1. Furthermore, a mixture of the glass particles and the phosphor nanoparticles 2 is fired and the obtained fired body is cut into a desired size, thus producing a second wavelength conversion layer 2. The obtained first wavelength conversion layer 1 and second wavelength conversion layer 2 are bonded together by thermocompression bonding or an adhesive, thus obtaining a wavelength conversion member 10.

(Light Emitting Device)

FIG. 2 is a schematic cross-sectional view showing a light emitting device according to an embodiment of the present invention. In the light emitting device 20, the wavelength conversion member 10 is placed on top of a light emitting element 4 placed on top of a substrate 3 and a reflective layer 5 is formed to cover the peripheries of the light emitting element 4 and the wavelength conversion member 10. In this embodiment, the wavelength conversion member 10 is placed so that the first wavelength conversion layer 1 side thereof faces the light emitting element 4. The wavelength conversion member 10 can be fixed on the light emitting element 4, for example, by providing a resin adhesive layer (not shown) between the first wavelength conversion layer 1 and the light emitting element 4. Note that in FIG. 2 the phosphor particles 1a and the phosphor nanoparticles 2a are not given.

Examples of the substrate 3 that can be used include white LTCCs (low temperature co-fired ceramics) capable of efficiently reflecting light emitted from the light emitting element 4. A specific example of the white LTCC is a sintered body of an inorganic powder, such as aluminum oxide, titanium oxide or niobium oxide, and a glass powder.

Alternatively, in order to efficiently dissipate heat emitted from the light emitting element 4, a ceramic substrate having high thermal conductivity may be used as the substrate 3. The ceramic substrate is preferred because it has excellent thermal resistance and weather resistance. Examples of the material for the ceramic substrate include aluminum oxide and aluminum nitride.

Examples of the light emitting element 4 include light sources capable of emitting a blue light, such as an LED light source and a laser light source.

The reflective layer 5 is provided in order to reflect light having leaked from the light emitting element 4 and the wavelength conversion member 10. The reflective layer 5 is formed, for example, of a resin (highly reflective resin) containing a white pigment, such as titanium oxide.

### EXAMPLES

Hereinafter, the present invention will be described in more detail with reference to specific examples, but the present invention is not at all limited to the following examples and can be embodied in appropriately modified forms without changing the gist of the invention.

Tables 1 and 2 show Examples (Nos. 1 to 6) of the present invention and Comparative Examples (Nos. 7 to 11).

TABLE 1

| | No.1 | No.2 | No.3 | No.4 | No.5 | No.6 | No.7 |
|---|---|---|---|---|---|---|---|
| Concentration of First Phosphor | 13 | 13 | 13 | 13 | 13 | 13 | 13 |
| Particles (% by mass) | | | | | | | |
| Thickness of First Wavelength | 0.10 | 0.10 | 0.10 | 0.07 | 0.07 | 0.07 | 0.20 |
| Conversion Layer (mm) | | | | | | | |
| Concentration of Phosphor | 10 | 15 | 20 | 10 | 15 | 20 | — |
| Nanoparticles (% by mass) | | | | | | | |
| Thickness of Second Wavelength | 0.10 | 0.10 | 0.10 | 0.13 | 0.13 | 0.13 | — |
| Conversion Layer (mm) | | | | | | | |
| Color of Appearance When not | pale | pale | pale | pale | white | white | yellow |
| Irradiated with Excitation Light | yellow | yellow | yellow | yellow | | | |
| Relative Luminous Flux | 0.91 | 0.89 | 0.88 | 0.86 | 0.85 | 0.84 | 1 |
| Homogeneity of Luminescent Color | Good | Good | Good | Good | Good | Good | Poor |

TABLE 2

| | No. 8 | No. 9 | No. 10 | No. 11 |
|---|---|---|---|---|
| Concentration of First Phosphor | 13 | 13 | 13 | 13 |
| Particles (% by mass) | | | | |
| Thickness of First Wavelength | 0.07 | 0.07 | 0.10 | 0.13 |
| Conversion Layer (mm) | | | | |
| Concentration of TiO₂ Particles | 5 | 10 | 10 | 10 |
| (% by mass) | | | | |
| Thickness of Scattering Layer (mm) | 0.13 | 0.13 | 0.10 | 0.07 |
| Color of Appearance When not | pale | white | white | pale |
| Irradiated with Excitation Light | yellow | | | yellow |
| Relative Luminous Flux | 0.8 | 0.65 | 0.73 | 0.8 |
| Homogeneity of Luminescent Color | Good | Good | Good | Good |

(Production of Wavelength Conversion Members Nos. 1 to 6)

YAG phosphor Particles having an average particle diameter of 15 μm were added to a borosilicate glass powder (softening point: 850° C., average particle diameter: 2.3 μm) and a binder resin (OLYCOX manufactured by Kyoeisha Chemical Co., Ltd.), a plasticizer (DOA manufactured by GOO Chemical Co., Ltd.), a dispersant (FLOWLEN G-700 manufactured by Kyoeisha Chemical Co., Ltd.), and an organic solvent (methyl ethyl ketone) were further added to the mixture, followed by kneading them to obtain a mixture in slurry form. The obtained mixture in slurry form was formed into a sheet by the doctor blade method and dried at room temperature, thus obtaining a first green sheet. The amount of YAG phosphor particles added was adjusted to reach the concentration shown in Table 1 in the first wavelength conversion layer.

A dispersant (FLOWLEN G-700 manufactured by Kyoeisha Chemical Co., Ltd.) and an organic solvent (methyl ethyl ketone) were added to YAG phosphor nanoparticles having an average particle diameter of 150 nm, followed by mixing them to produce a dispersion liquid of YAG phosphor nanoparticles. A borosilicate glass powder (softening point: 850° C., average particle diameter: 2.3 μm), a binder resin (OLYCOX manufactured by Kyoeisha Chemical Co., Ltd.), and a plasticizer (DOA manufactured by GOO Chemical Co., Ltd.) were added to the obtained dispersion liquid, followed by mixing them to obtain a mixture in slurry form. The obtained mixture in slurry form was formed into a sheet by the doctor blade method and dried at room temperature, thus obtaining a second green sheet. The amount of YAG phosphor nanoparticles added was adjusted to reach each concentration shown in Table 1 in the second wavelength conversion layer.

The first green sheet and the second green sheet were cut into respective predetermined sizes and then bonded together by thermocompression. The obtained laminate was subjected to degreasing treatment in an electric furnace and then subjected to vacuum firing at around the softening point of the glass powder in a gas convertible vacuum furnace. The obtained fired body was polished one side after the other to have a desired layer thickness, thus obtaining a wavelength conversion member in which a first wavelength conversion layer and a second wavelength conversion layer were laid one on top of the other. The surface roughness Raᵢₙ of the first wavelength conversion layer was 0.02 μm and the surface roughness Raₒᵤₜ of the second wavelength conversion layer was 0.02 μm.

(Production of Wavelength Conversion Member No. 7)

Only the first green sheet obtained in Examples 1 to 6 was subjected to degreasing treatment in an electric furnace and then subjected to vacuum firing at around the softening point of the glass powder in a gas convertible vacuum furnace. The obtained fired body was polished, thus obtaining a wavelength conversion member formed only of a first wavelength conversion layer.

(Production of Wavelength Conversion Members Nos. 8 to 11)

Wavelength conversion members were produced in the same manner as in Examples 1 to 6 except that TiO₂ particles having an average particle diameter of 100 nm were used instead of the YAG phosphor nanoparticles. Each of the wavelength conversion members was a laminate in which a scattering layer containing TiO₂ particles was formed on a surface of a first wavelength conversion layer. The amount of TiO₂ particles added was adjusted to reach each concentration shown in Table 2 in the scattering layer.

(Evaluations on Luminous Flux and Homogeneity of Luminescent Color)

The obtained wavelength conversion members were measured in terms of luminescence intensity (total luminous flux) in the following manner. In a state where each wavelength conversion member was disposed above a light source having an excitation wavelength of 450 nm so that the first wavelength conversion layer was in contact with the light source, the light source was turned on. Light emitted from the wavelength conversion member was taken into an integrating sphere, guided to a spectrometer calibrated by a reference light source, and measured in terms of spectral energy distribution with the spectrometer. The obtained spectra were multiplied by the standard spectral luminous efficiency function to calculate a total luminous flux. The results are shown in Tables 1 and 2. Note that the total luminous fluxes are expressed as values relative to the luminescence intensity of the wavelength conversion member sample No. 7 assumed to be 1.

Furthermore, in a state where each wavelength conversion member was disposed above a light source having an excitation wavelength of 450 nm so that the first wavelength conversion layer was in contact with the light source, the light source was turned on to project, on a screen, light emitted from the wavelength conversion member. The homogeneity of light projected on the screen was visually observed. The wavelength conversion members found to have little unevenness of luminosity and therefore to have excellent homogeneity of luminosity were evaluated to be good as indicated by a “Good” sign, whereas the wavelength conversion member found to have large unevenness of luminosity and therefore to have poor homogeneity of luminosity was evaluated to be no good as indicated by a “Poor” sign.

The wavelength conversion members Nos. 1 to 6, which were examples of the present invention, showed white to pale yellow appearances when not irradiated with excitation light, and therefore showed excellent aesthetic appearances. In addition, they exhibited relative luminous fluxes of 0.84 or more, i.e., high luminescence intensities, and also exhibited an excellent homogeneity of luminescent color. On the other hand, the wavelength conversion member No. 7, which was a comparative example, showed a yellow appearance when not irradiated with excitation light, and therefore showed a poor aesthetic appearance. In addition, the homogeneity of luminescent color was poor. The wavelength conversion members Nos. 8 to 11, which were comparative examples, exhibited relative luminous fluxes of 0.8 or less, i.e., low luminescence intensities.

### REFERENCE SIGNS LIST

1 first wavelength conversion layer
1a phosphor particle
2 second wavelength conversion layer
2a phosphor nanoparticle
3 substrate
4 light source
5 reflective layer
10 wavelength conversion member

1. A wavelength conversion member comprising:
a first wavelength conversion layer containing a phosphor; and
a second wavelength conversion layer formed on a surface of the first wavelength conversion layer and containing phosphor nanoparticles.

2. The wavelength conversion member according to claim 1, wherein the phosphor contained in the first wavelength conversion layer is phosphor particles having an average particle diameter of 1 μm or more.

3. The wavelength conversion member according to claim 1, wherein the phosphor nanoparticles have an average particle diameter of 10 to 400 nm.

4. The wavelength conversion member according to claim 1, wherein a concentration of the phosphor nanoparticles in the second wavelength conversion layer is 5 to 40% by mass.

5. The wavelength conversion member according to claim 1, wherein the second wavelength conversion layer has a thickness of 0.01 to 1 mm.

6. The wavelength conversion member according to claim 1, wherein the second wavelength conversion layer has a thickness equal to or larger than a thickness of the first wavelength conversion layer.

7. The wavelength conversion member according to claim 1, wherein the second wavelength conversion layer comprises a matrix made of an inorganic material and the phosphor nanoparticles dispersed in the matrix.

8. The wavelength conversion member according to claim 7, wherein the matrix is a glass matrix.

9. The wavelength conversion member according to claim 1, wherein the first wavelength conversion layer has a thickness of 0.01 to 1 mm.

10. The wavelength conversion member according to claim 1, wherein the first wavelength conversion layer comprises a matrix made of an inorganic material and the phosphor particles dispersed in the matrix.

11. The wavelength conversion member according to claim 10, wherein the matrix is a glass matrix.

12. The wavelength conversion member according to claim 1, wherein the first wavelength conversion layer is made of a ceramic.

13. A light emitting device comprising:
the wavelength conversion member according to claim 1; and
a light source capable of irradiating the wavelength conversion member with excitation light.

14. A method for producing the wavelength conversion member according to claim 1, the method comprising the steps of:
preparing a green sheet for the first wavelength conversion layer and a green sheet for the second wavelength conversion layer;
laying the green sheet for the first wavelength conversion layer and the green sheet for the second wavelength conversion layer one on top of the other to obtain a laminate; and
firing the laminate to obtain a sintered body in which the first wavelength conversion layer and the second wavelength conversion layer are laid one on top of the other.

15. The method for producing the wavelength conversion member according to claim 14, wherein the laminate is fired while being restrained between a pair of restraint members.

16. The method for producing the wavelength conversion member according to claim 14, wherein the first wavelength conversion layer and/or the second wavelength conversion layer in the sintered body are polished.

17. The method for producing the wavelength conversion member according to claim 16, wherein the second wavelength conversion layer in the sintered body is polished to have a predetermined thickness and the first wavelength conversion layer in the sintered body is then polished to adjust a chromaticity of the wavelength conversion member.
